(19) United States
(12) Patent Application Publication
(10) Pub. No.: US 2025/0070732 A1
(43) Pub. Date: Feb. 27, 2025

(54) POWER AMPLIFYING CIRCUIT

(71) Applicant: Murata Manufacturing Co., Ltd., Kyoto (JP)

(72) Inventors: Masao KONDO, Kyoto (JP); Shinnosuke TAKAHASHI, Kyoto (JP); Shaojun MA, Kyoto (JP)

(21) Appl. No.: 18/944,599

(22) Filed: Nov. 12, 2024

Related U.S. Application Data
(63) Continuation of application No. PCT/JP2023/017402, filed on May 9, 2023.

(30) Foreign Application Priority Data
May 20, 2022 (JP) 2022-082800

(51) Int. Cl. H03F 3/24; H03F 1/30

(52) U.S. Cl. CPC H03F 3/245; H03F 1/305; H03F 2200/451; H03F 2200/468

(57) ABSTRACT

A power amplifying circuit includes an output transistor that amplifies a radio frequency signal and outputs an amplified signal, a bias circuit that supplies a bias current or voltage to the output transistor, and a bias control part connected to the bias circuit and includes a control circuit that increases the bias current or voltage when an ambient temperature is equal to or less than a predetermined value. In consecutive time periods of a first, a second, and a third time period, when output of the output transistor in the third time period is greater than output of the output transistor in the first and the second time period, the bias control part increases the bias current or voltage in the second time period as to become higher than the bias current or voltage of a case where the ambient temperature is higher than the predetermined threshold value.

### CROSS REFERENCE TO RELATED APPLICATION

This is a continuation of International Application No. PCT/JP2023/017402 filed on May 9, 2023 which claims priority from Japanese Patent Application No. 2022-082800 filed on May 20, 2022. The contents of these applications are incorporated herein by reference in their entireties.

### BACKGROUND ART

### Technical Field

The present disclosure relates to power amplifying circuits.

For communication using mobile objects such as portable devices and the like, a power amplifying circuit that amplifies a radio frequency (RF) signal is used. As control methods for amplifying a RF signal efficiently, an envelope tracking (ET) control and an average power tracking (APT) control are known in the art. The ET control and the APT control are control methods for amplifying power using a power source voltage that varies in a manner that depends on the amplitude of a radio frequency signal. The correlation between the radio frequency signal amplitude and the power source voltage is set in a control IC. The power source voltage is, for example, set in such a manner as to reach about 5.5 V at a maximum.

For the power amplifying circuit in which the power source voltage is supplied to a transistor, the transistor is required not to break down even when the output load changes as long as the ambient temperature, which is the temperature in the outside of the power amplifying circuit, is within a certain temperature range (for example, −30 degrees C. to 85 degrees C.). Patent Document 1 describes a power amplifying circuit that controls a thermal operation state of a semiconductor power amplifying element in such a way that the thermal operation state becomes a predetermined power amplifying state before starting the amplification of radio frequency power in order to alleviate or dissolve variation of the characteristics after the start of the amplification.

Patent Document 1: Japanese Unexamined Patent Application Publication No. 2003-338712

### BRIEF SUMMARY

Particularly, when the ambient temperature is low (for example, −30 degrees C.), there is a problem in that a relatively high value of the power source voltage causes breakdown of a transistor in an output stage when the output load changes. In the power amplifying circuit of Patent Document 1, the thermal operation state of a power amplifying element (transistor) is controlled. However, for example, no distinction is made between low temperature and ordinary temperature, and the control to increase the temperature of the power amplifying element is performed even at ordinary temperature at which the control of the thermal operation state is not needed and in other similar cases. As a result, the current consumption of the power amplifying circuit increases.

The present disclosure provides a power amplifying circuit that enables improvement of resistance to voltage breakdown of a transistor in a low temperature environment and reduction of current consumption of the power amplifying circuit.

A power amplifying circuit according to one aspect of the present disclosure includes: an output transistor that amplifies a radio frequency signal and outputs an amplified signal, an amount of heat generation of the output transistor increasing with an increase of a current passing therethrough; a bias circuit part that supplies a bias current or voltage to the output transistor; and a bias control part that is connected to the bias circuit part and includes a control circuit that increases the bias current or voltage when an ambient temperature is equal to or less than a predetermined threshold value, wherein in consecutive time periods of a first time period, a second time period, and a third time period, when output of the output transistor in the third time period is greater than output of the output transistor in the first time period and the second time period, the bias control part increases the bias current or voltage in the second time period in such a manner as to become higher than the bias current or voltage of a case where the ambient temperature is higher than the predetermined threshold value.

According to the present disclosure, it becomes possible to provide a power amplifying circuit that enables the improvement of resistance to voltage breakdown of a transistor in a low temperature environment and the reduction of current consumption of the power amplifying circuit.

### BRIEF DESCRIPTION OF THE DRAWINGS

FIG. 1 is a circuit diagram of a power amplifying circuit according to a first embodiment.

FIG. 2 is a graph for illustrating operation of the power amplifying circuit according to the first embodiment.

FIG. 3 is a graph for illustrating operation of the power amplifying circuit according to the first embodiment.

FIG. 4 is a graph for illustrating operation of a power amplifying circuit according to a second embodiment.

FIG. 5 is a graph for illustrating operation of a power amplifying circuit according to a third embodiment.

FIG. 6 is a graph for illustrating operation of the power amplifying circuit according to the third embodiment.

FIG. 7 is a graph for illustrating operation of the power amplifying circuit according to the third embodiment.

FIG. 8 is a graph for illustrating operation of the power amplifying circuit according to the third embodiment.

FIG. 9 is a graph for illustrating operation of a power amplifying circuit according to a fourth embodiment.

FIG. 10 is a graph for illustrating operation of the power amplifying circuit according to the fourth embodiment.

FIG. 11 is a graph for illustrating operation of the power amplifying circuit according to the fourth embodiment.

FIG. 12 is a circuit diagram of a power amplifying circuit according to a fifth embodiment.

FIG. 13 is a graph for illustrating bias control of the power amplifying circuit according to the fifth embodiment.

FIG. 14 is a graph for illustrating operation of the power amplifying circuit according to the fifth embodiment.

### DETAILED DESCRIPTION

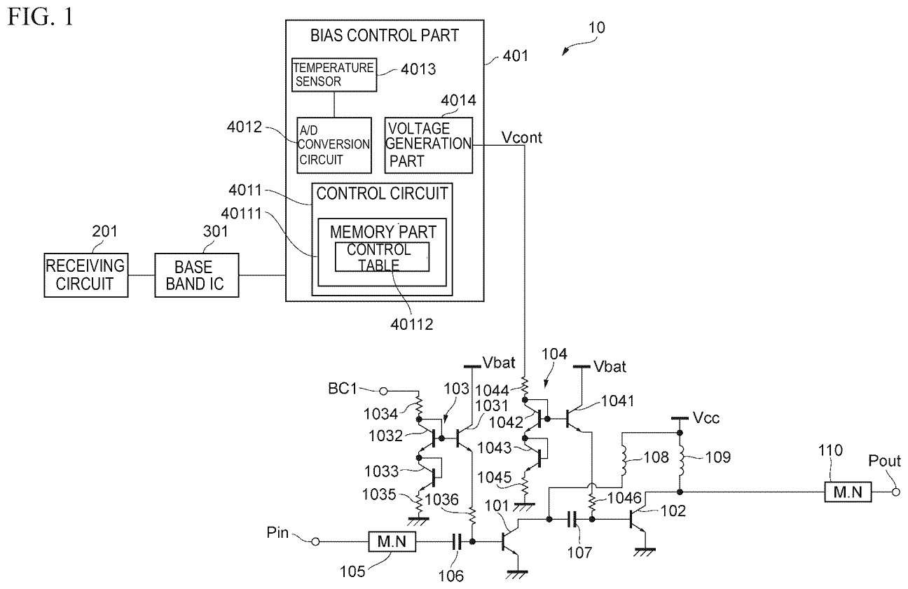

A first embodiment is described. FIG. 1 is a circuit diagram of a power amplifying circuit 10 according to the first embodiment. The power amplifying circuit 10 according to the first embodiment performs amplification for communication using a Time Division Duplex (TDD) system. The power amplifying circuit 10 includes a transistor 101, an output transistor 102, bias circuits 103 and 104, matching circuits 105 and 110, capacitors 106 and 107, inductors 108 and 109, and resistive elements 1036 and 1046. Further, the power amplifying circuit 10 includes a receiving circuit 201, a base band IC 301, and a bias control part 401.

The base of the transistor 101 is connected to an input port Pin via the matching circuit 105 and the capacitor 106. Further, a bias current or voltage is supplied from the bias circuit 103 to the base of the transistor 101. A power source voltage Vcc is supplied to the collector of the transistor 101 via the inductor 108. The emitter of the transistor 101 is connected to ground. The transistor 101 amplifies a radio frequency signal input via the input port Pin and outputs an amplified signal to the base of the output transistor 102.

The base of the output transistor 102 is connected to the collector of the transistor 101 via the capacitor 107. Further, a bias current or voltage is supplied from the bias circuit 104 to the base of the output transistor 102. The power source voltage Vcc is supplied to the collector of the output transistor 102 via the inductor 109. The emitter of the transistor 101 is connected to the ground. The output transistor 102 amplifies a signal from the transistor 101 and outputs an output signal from the collector of the output transistor 102 to an output terminal Pout via the matching circuit 110.

The bias circuit 103 includes transistors 1031, 1032, and 1033 and resistive elements 1034 and 1035.

The base of the transistor 1031 is connected to the resistive element 1034 and the collector of the transistor 1032. Furthermore, the collector and the emitter of the transistor 1031 are connected to a power source and the resistive element 1036, respectively. The ON state and the OFF state of the transistor 1031 are switched by a current that is supplied to the base of the transistor 1031 on the basis of a control signal that is supplied from a control input port BC1 and flows through the resistive element 1034. When the transistor 1031 is in the ON state, the transistor 1031 outputs the bias current or voltage.

The transistor 1032 is a diode-connected transistor. The collector of the transistor 1032 is connected to resistive element 1034 and the base of the transistor 1031, and the emitter of the transistor 1032 is connected to the collector of the transistor 1033. The transistor 1032 outputs a current to the collector of the transistor 1033 on the basis of a current flowing through the collector of the transistor 1032.

The transistor 1033 is a diode-connected transistor. The collector of the transistor 1033 is connected to the emitter of the transistor 1032, and the emitter of the transistor 1033 is connected to the ground via the resistive element 1035. The transistor 1033 outputs a current from its emitter on the basis of the current from the transistor 1032.

The resistive element 1034 and the resistive element 1035 are provided to cause a predetermined voltage drop based on a current Ic.

The resistive element 1036 is provided between the emitter of the transistor 1031 and the base of the transistor 101. The resistive element 1036 is provided to cause a predetermined voltage drop based on the bias current from the transistor 1031.

The bias circuit 104 includes transistors 1041, 1042, and 1043 and resistive elements 1044 and 1045. The connection relationship among all the elements of the bias circuit 104 is similar to that of the bias circuit 103. The bias circuit 104 supplies a bias current or voltage to the base of the output transistor 102. The resistive element 1046 is provided to cause a predetermined voltage drop based on the bias current from the transistor 1041.

The matching circuit 105 is provided between the input port Pin and the capacitor 106. The matching circuit 105 provides impedance matching between the input port Pin and the base of the transistor 101.

The capacitor 106 is provided between the matching circuit 105 and the base of the transistor 101. The capacitor 106 has the capability of cutting a DC component of a signal input to the transistor 101.

The capacitor 107 is provided between the collector of the transistor 101 and the base of the output transistor 102. The capacitor 107 has the capability of cutting a DC component of a signal input to the output transistor 102.

The inductor 108 is provided between the collector of the transistor 101 and a power line that supplies the power source voltage Vcc. The inductor 109 is provided between the collector of the transistor 101 and a power line that supplies the power source voltage Vcc. Each of the inductors 108 and 109 functions as a choke inductor.

The matching circuit 110 provides impedance matching between the collector of the output transistor 102 and the output terminal Pout.

The receiving circuit 201 receives a receiving signal from a communication base station. Further, the receiving circuit 201 receives, from a communication base station, a signal that distinguishes between a transmitting time slot (time period allocated for transmitting) and a receiving time slot (time period allocated for receiving), or an output display signal that indicates the magnitude of transmitting power, or both. These signals may be, for example, obtained as a switching signal indicating timing of transmitting power switching and an output display signal for each time period.

The base band IC 301 is connected to the receiving circuit 201. The base band IC 301 receives the switching signal or the output display signal or both from the receiving circuit 201. The base band IC 301 outputs, to the bias control part 401, a signal indicating whether the communication in a TDD system is in the transmitting slot in which signal amplification is needed or in the receiving time slot in which no signal amplification is needed.

The bias control part 401 includes a control circuit 4011, an A/D conversion circuit 4012, a temperature sensor 4013, and a voltage generation part 4014.

The control circuit 4011 includes a memory part 40111. The memory part 40111 stores therein a control table 40112 in which a control voltage Vcont is defined, and this control voltage Vcont is based on the signal from the base band IC 301 and a temperature signal that has been converted to a digital signal.

The A/D conversion circuit 4012 converts a temperature signal that is an analog signal sent from the temperature sensor 4013 measuring an ambient temperature into a digital signal.

The temperature sensor 4013 is a circuit element for measuring the ambient temperature around the power amplifying circuit 10. The temperature sensor 4013 may be placed on a semiconductor chip that is the same semiconductor chip in which the power amplifying circuit 10 is provided or may be placed on a different semiconductor chip. Alternatively, the temperature sensor 4013 may be placed on an arbitrary position of the device in which the power amplifying circuit 10 is provided.

The voltage generation part 4014 is connected to the resistive element 1044 of the bias circuit 104. The voltage generation part 4014 outputs the control voltage Vcont on the basis of the control table 40112.

The signal that distinguishes the transmitting time slot and the receiving time slot is input to the bias control part 401 from the base band IC 301. Further, the bias control part 401 obtains the ambient temperature measured by the temperature sensor 4013 as an analog signal. This temperature signal is converted into a digital signal by the A/D conversion circuit 4012. The signal from the base band 301 and the temperature signal that has been converted into a digital signal are transmitted to the control circuit 4011. The control circuit 4011 refers to the control table 40112 stored in the memory part 40111 and determines the control voltage Vcont to be output from the voltage generation part 4014. The voltage generation part 4014 supplies the control voltage Vcont to the bias circuit 104 on the basis of the determined voltage.

The voltage generation part 4014 supplies a bias current to the output transistor 102 in such a way that when the ambient temperature is low, an idle current flowing into the collector of the output transistor 102 in the receiving time slot is higher than the idle current in the transmitting time slot.

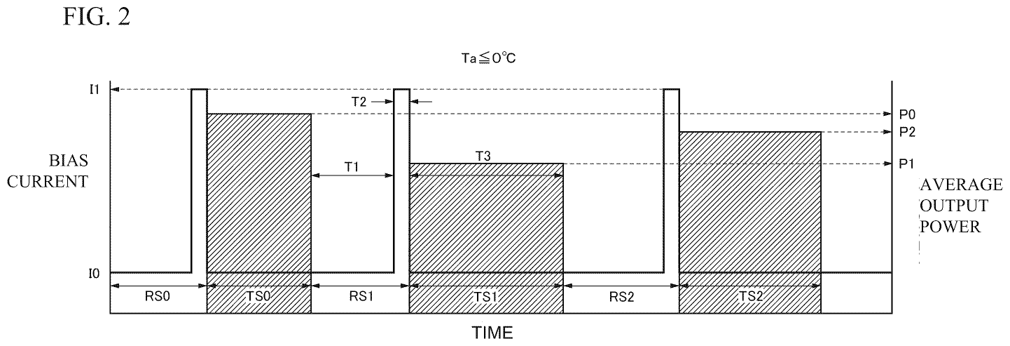

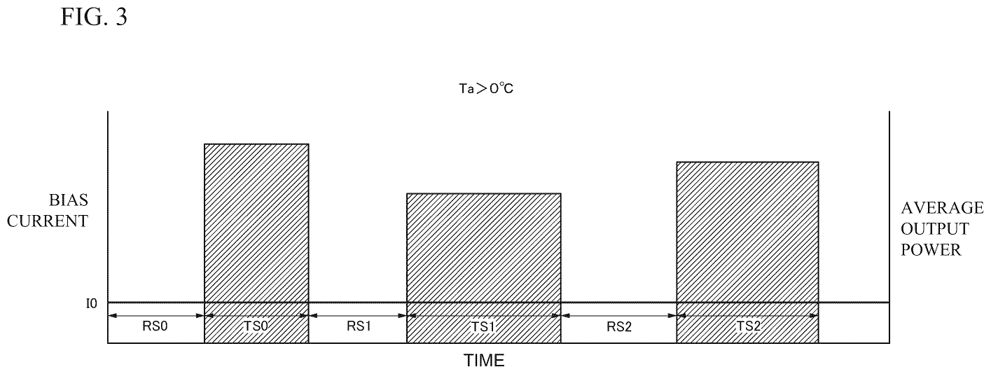

Referring to FIG. 2 and FIG. 3, the control of the bias current (or the bias voltage) performed by the bias control part 401 is described.

FIG. 2 is a graph illustrating the variation of the bias current with time and the variation of the average output power of the output transistor 102 with time in communication of a TDD system. In the TDD system, the receiving time slot and the transmitting time slot are repeated in an alternating fashion, and in the transmitting time slot, the output transistor 102 amplifies the power of a transmitting signal. In FIG. 2, a receiving time slot RS0 is followed by a transmitting time slot TS0, a receiving time slot RS1 is followed by a transmitting time slot TS1, and a receiving time slot RS2 is followed by a transmitting time slot TS2.

The output transistor 102 performs the amplification operation only in the transmitting time slots TS0, TS1, and TS2. In FIG. 2, the output transistor 102 amplifies power in such a way that the average output power becomes P0, P1, and P2 (right axis in FIG. 2) in the transmitting time slots TS0, TS1, and TS2, respectively. On the other hand, in the receiving time slots RS0, RS1, and RS2, the output transistor 102 does not perform the amplification operation. Although the output transistor 102 does not perform the amplification operation in the receiving time slots RS0, RS1, and RS2, a predetermined bias current I0 (left axis in FIG. 2) is supplied to the output transistor 102.

The operation of the control circuit 4011 is described. Here, the description is provided while focusing on the receiving time slot RS1 and the transmitting time slot TS1. The receiving time slot RS1 includes a time period T1 (first time period) and a time period T2 (second time period) that continues from the time period T1. The transmitting time slot TS1 includes a time period T3 (third time period) that continues from the time period T2. That is to say, the time periods T1, T2, and T3 continue without necessarily interruption. Further, the time period T2 is, for example, about 200 μs and is shorter than the time period T1.

The control circuit 4011 (a) obtains through the temperature signal indicating the ambient temperature Ta measured by the temperature sensor 4013 from the A/D conversion circuit 4012, (b) obtains the signal that distinguishes between the transmitting time slot and the receiving time slot from the base band IC 301, and (c) determines the control voltage Vcont to be output from the voltage generation part 4014 in a manner that depends on the ambient temperature Ta by referring to the control table 40112.

For example, as illustrated in FIG. 2, the control table 40112 stores therein information that causes the control voltage Vcont to be output in such a way that a bias current I1 that is greater than the bias current I0 is supplied to the output transistor 102 in the time period T2 in a square pulse-like waveform when the ambient temperature Ta is equal to or less than a predetermined threshold value (for example, 0 degrees C.). Further, the control voltage Vcont is output in such a way that the bias current I1 returns to the bias current I0 at the start of the time period T3.

Further, as illustrated in FIG. 3, the control table 40112 stores therein information that causes the control voltage Vcont to be output in such a way that the bias current I0 is supplied to the output transistor 102 even in the time period T2 when the ambient temperature Ta is higher than the predetermined threshold value (for example, 0 degrees C.).

As described above, in the power amplifying circuit 10, when the ambient temperature Ta is equal to or less than the predetermined threshold value, the bias current supplied to the output transistor 102 is increased in the time period T2 that is close to the time immediately before the start of the amplification of the transmitting signal. Because of this, the temperature of the output transistor 102 can be increased to an ordinary temperature. Because of this, the breakdown voltage of the output transistor 102 at the start of transmitting can be increased to, for example, a value comparable to that of the case where the ambient temperature is higher than the threshold value.

Further, in the power amplifying circuit 10, the bias current is increased when the ambient temperature is equal to or less than the predetermined threshold value. Thus, the breakdown voltage can be increased when the ambient temperature is a temperature at which the breakdown voltage needs to be increased. Therefore, compared with a case where the bias current supplied to the output transistor 102 is increased in the time period T2 regardless of the ambient temperature, an increase in power consumption of the power amplifying circuit 10 can be suppressed.

Even in the case where the bias current I1 is returned to the bias current I0 at the same time as the start of the time period T3, self-heating of the output transistor 102 caused by the amplification of the transmitting signal starts in the time period T3. Therefore, no temperature decrease occurs in the output transistor 102, and the state of high breakdown voltage is maintained. Because the bias current I0 in the time period T3 is set to an appropriate value for characteristics of the transmitting signal such as distortion and the like, degradation of the transmitting characteristics can be suppressed by increasing the bias current in the time period T2. Further, by causing the bias current to have a high value like the bias current I1 only in a short period of time, that is, the time period T2, a greater breakdown voltage improvement can be achieved.

The second embodiment is described. In the second embodiment and subsequent embodiments, descriptions regarding matters common to the first embodiment will be omitted, and only features different from the first embodiment will be described. Particularly, similar actions and effects produced by similar constituent elements will not be repeated in each embodiment.

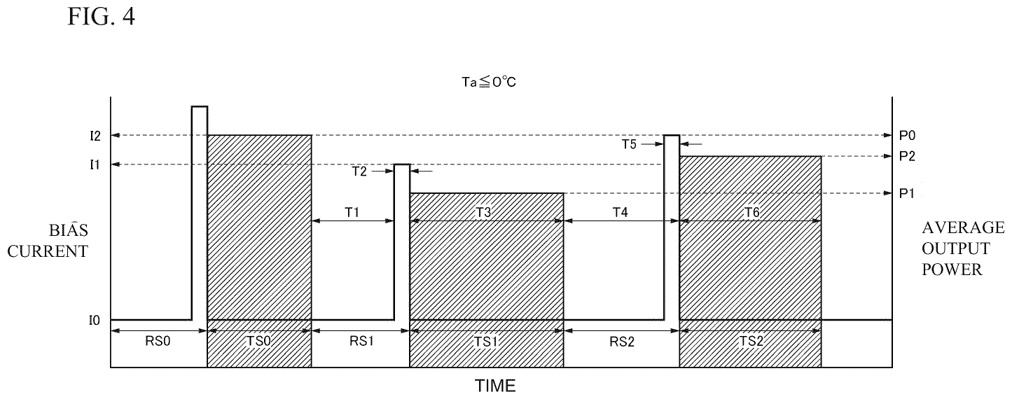

In the second embodiment, the control performed by the bias control part 401 is different from the control of the first embodiment but the other features are common to the first embodiment. Referring to FIG. 4, the control of the bias current (or the bias voltage) performed by the bias control part 401 of the second embodiment is described.

The control circuit 4011 (a) obtains through the temperature signal indicating the ambient temperature Ta measured by the temperature sensor 4013 from the A/D conversion circuit 4012, (b-1) obtains the signal that distinguishes between the transmitting time slot and the receiving time slot from the base band IC 301, (b-2) obtains the output display signal indicating the magnitude of transmitting power from the base band IC 301 and, and (c) determines the control voltage Vcont to be output from the voltage generation part 4014 in a manner that depends on the ambient temperature Ta and the magnitude of transmitting power by referring to the control table 40112. For example, the control voltage Vcont may be determined on the basis of the difference between the average transmitting power in the transmitting time slot and the average transmitting power in the receiving time slot. Note that the output of the receiving time slot may be zero as illustrated in FIG. 4. In the case of FIG. 4, the receiving circuit 201 further obtains an output display signal indicating the average output power P1 of output of the output transistor in the time period T3 and the average output power (not illustrated) of output of the output transistor in the time period T1 and the time period T2, and the control circuit 4011 determines the control voltage Vcont.

For example, as illustrated in FIG. 4, the control table 40112 stores therein information that causes the control voltage Vcont to be output in such a way that the bias current I1 that is greater than the bias current I0 is supplied to the output transistor 102 in the time period T2 in a square pulse-like waveform on the basis of the output display signal in the time period T3 when the ambient temperature Ta is equal to or less than a predetermined threshold value (for example, 0 degrees C.). Further, the control voltage Vcont is output in such a way that the bias current I1 returns to the bias current I0 at the start of the time period T3.

Further, the focus is now turned to the receiving time slot RS2 including a time period T4 and a time period T5 that continues from the time period T4 and the transmitting time slot TS2 including a time period T6 that continues from the time period T5. In this case, similarly, the time periods T4, T5, and T6 continue without necessarily interruption. Here, the average output power P2 in the transmitting time slot TS2 is higher than the average output power P1 in the transmitting time slot TS1.

At this case, the control table 40112 stores therein information that causes the control signal Vcont to be output in such a way that a bias current I2 that is greater than the bias currents I0 and I1 is supplied to the output transistor 102 in the time period T5 in a square pulse-like waveform.

As described above, the bias control part 401 of the second embodiment outputs the control signal Vcont in such a way that the magnitude of the bias current supplied to the output transistor 102 varies in a manner that depends on the output power of the transmitting signal.

When the average transmitting power of transmitting power is small, the power to be amplified by the output transistor 102 is suppressed. Thus, the breakdown voltage of the output transistor 102 can be increased sufficiently even when the magnitude of the bias current to be increased transiently is reduced compared with the case where the average transmitting power is high. Regardless of the average transmitting power, the power amplifying circuit 10 of the second embodiment enables the reduction of power consumption compared with the case where the bias current is increased transiently.

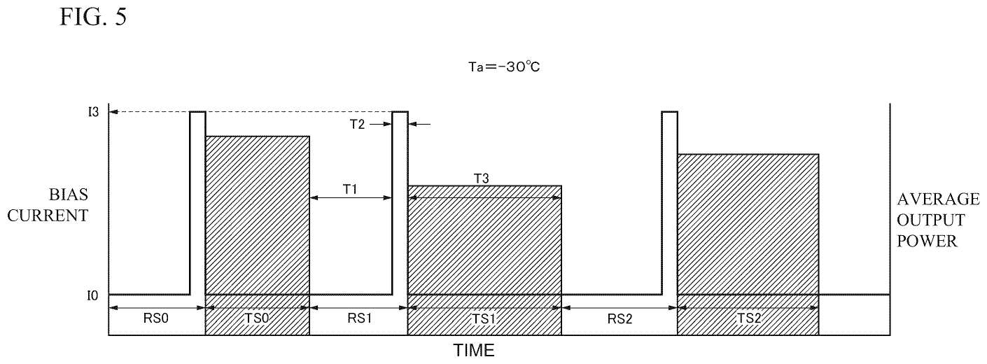

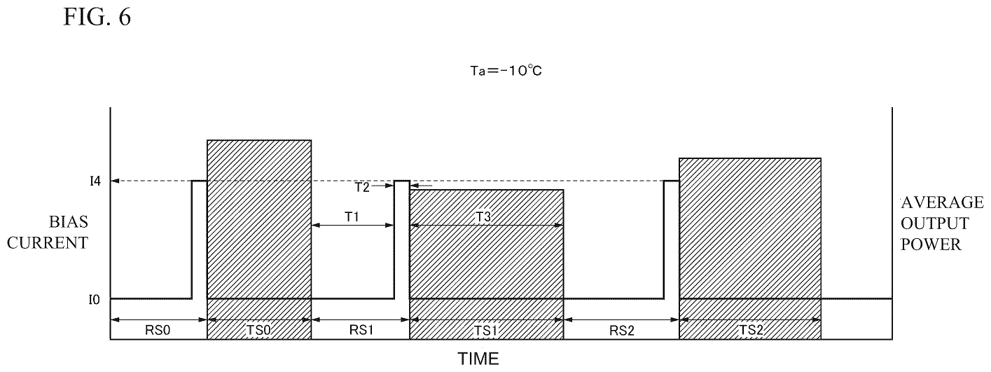

The third embodiment is described. In the third embodiment, the control performed by the bias control part 401 is different from the control of the first embodiment but the other features are common to the first embodiment. Referring to FIG. 5 and FIG. 6, the control of the bias current (or the bias voltage) performed by the bias control part 401 of the third embodiment is described.

The control circuit 4011 (a) obtains through the temperature signal indicating the ambient temperature Ta measured by the temperature sensor 4013 from the A/D conversion circuit 4012, (b) obtains the signal that distinguishes between the transmitting time slot and the receiving time slot from the base band IC 301, and (c) determines the control voltage Vcont to be output from the voltage generation part 4014 in a manner that depends on the ambient temperature Ta and the magnitude of transmitting power by referring to the control table 40112.

The third embodiment is different from the first embodiment in that a bias current to be increased individually for an ambient temperature below the threshold value is set in the control table 40112.

For example, as illustrated in FIG. 5, the control table 40112 stores therein information that causes the control voltage Vcont to be output in such a way that a bias current I3 that is greater than the bias current I0 is supplied to the output transistor 102 in the time period T2 in a square pulse-like waveform when the ambient temperature Ta is equal to or less than a predetermined threshold value (for example, 0 degrees C.) and the ambient temperature Ta is −30 degrees C. Further, the control voltage Vcont is output in such a way that the bias current I3 returns to the bias current I0 at the start of the time period T3.

For example, as illustrated in FIG. 6, the control table 40112 stores therein information that causes the control voltage Vcont to be output in such a way that a bias current I4 that is greater than the bias current I0 and less than the bias current I3 is supplied to the output transistor 102 in the time period T2 in a square pulse-like waveform when the ambient temperature Ta is equal to or less than a predetermined threshold value (for example, 0 degrees C.) and the ambient temperature Ta is −10 degrees C.

Even in the case where the ambient temperature is equal to or less than the threshold value, when the amount of drop from the threshold value is small, the amount of the bias current needed to increase the temperature of the output transistor 102 can be suppressed. Thus, even when the magnitude of the bias current is reduced compared with the case where the ambient temperature is lower, the breakdown voltage of the output transistor 102 can be increased sufficiently. Regardless of the ambient temperature, the power amplifying circuit 10 of the third embodiment enables the reduction of power consumption compared with the case where the bias current is increased transiently.

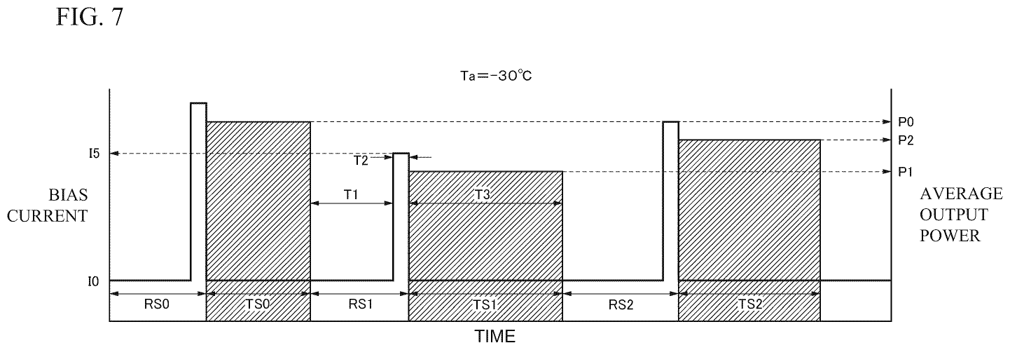

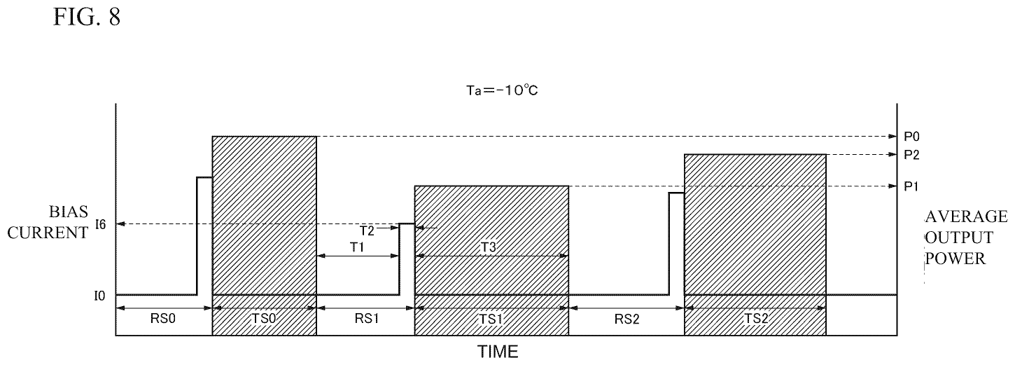

Here, it is possible to combine the control methods performed by the bias control part 401, which are respectively described in the second embodiment and the third embodiment. Referring to FIG. 7 and FIG. 8, examples are described for cases where the control methods are combined. FIG. 7 illustrates an example for the case where the ambient temperature Ta is −30 degrees C., and FIG. 8 illustrates an example for the case where the ambient temperature Ta is −10 degrees C.

As illustrated in FIG. 7, the bias control part 401 outputs the control voltage Vcont in such a way that the magnitude of the bias current supplied to the output transistor 102 varies in a manner that depends on the output power of the transmitting signal. In FIG. 8, the bias control part 401 similarly outputs the control voltage Vcont.

Comparing FIG. 7 and FIG. 8, for example, the bias current in the time period T2 is a bias current I5 in FIG. 7, and the bias current in the time period T2 is a bias current I6 that has a smaller current value than the bias current I5 in FIG. 8.

As described above, the power consumption can be suppressed further by combining the respective control methods of the second embodiment and the third embodiment.

The fourth embodiment is described. The power amplifying circuit 10 of the fourth embodiment is different from the power amplifying circuit 10 of the first embodiment using a TDD system in that the amplification is performed for communication using a Frequency Division Duplex (FDD) system, and the other features are common to the first embodiment except the followings.

The receiving circuit 201 receives a receiving signal from a communication base station. Further, the receiving circuit 201 receives, from a communication base station, a signal (output display signal) that indicates an average output power for each time window and a signal (switching signal) that indicates the timing of average output power switching. The signal that distinguishes the switching of average output power is obtained as the switching signal.

The base band IC 301 receives the switching signal or the output display signal or both from the receiving circuit 201. The base band IC 301 outputs the switching signal or the output display signal or both to the bias control part 401.

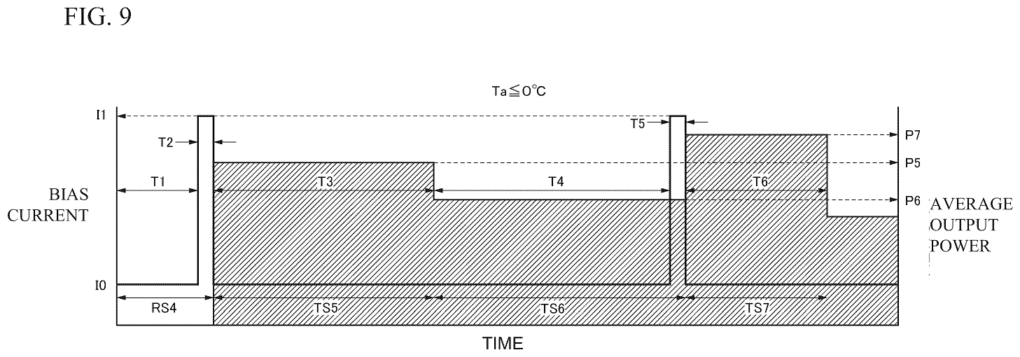

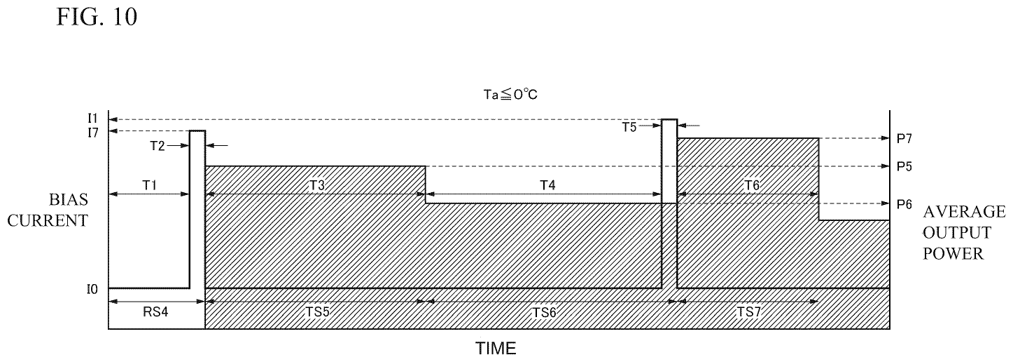

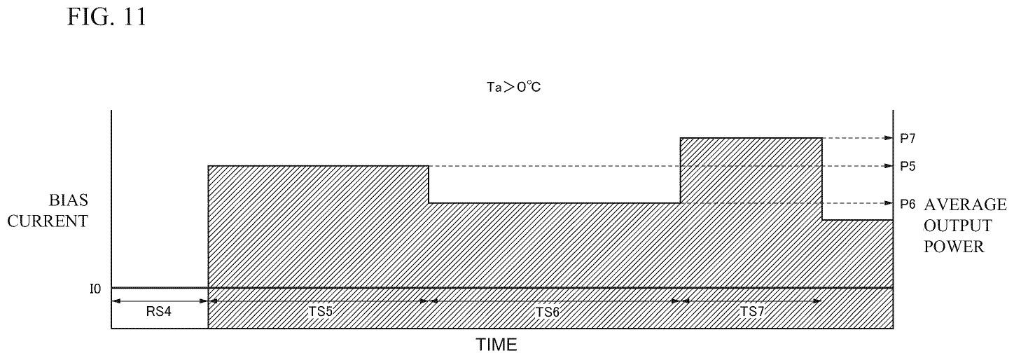

FIG. 9, FIG. 10, and FIG. 11 are graphs each illustrating the variation of the bias current with time and the variation of the average output power of the output transistor 102 with time in communication of a FDD system. The FDD system is a communication system that simultaneously transmits and receives a signal having a receiving frequency and a signal having transmitting frequency. As illustrated in FIG. 9, FIG. 10, and FIG. 11, in the FDD system, the average output power output from the output transistor 102 can be increased or decreased for each time window. FIG. 9 and FIG. 10 illustrate cases where the average output power is varied in each of time windows TS4, TS5, TS6, and TS7.

The control of the control circuit 4011 is described. The time window TS4 where the average output power becomes zero or extremely small includes the time period T1 and the time period T2 that continues from the time period T1. The time window TS5 includes the time period T3 that continues from the time period T2. That is to say, the time periods T1, T2, and T3 continue without necessarily interruption. Further, the time period T2 is, for example, about 200 μs and is shorter than the time period T1.

Further, the time window TS6 that continues from the time window TS5 includes the time period T4 and the time period T5 that continues from the time period T4. Further, the time window TS5 includes the time period T3 that continues from the time period T2.

In FIG. 9 and FIG. 10, the output transistor 102 amplifies power in such a way that the average output power becomes equal to P5, P6, and P7 (right axis in FIG. 2) in the time windows TS5, TS6, and TS7, respectively. The average output power P5 is lower than the average output power P6, and the average output power P7 is higher than the average output power P6.

The control circuit 4011 (a) obtains through the temperature signal indicating the ambient temperature Ta measured by the temperature sensor 4013 from the A/D conversion circuit 4012, (b) obtains the switching signal from the base band IC 301, and (c) determines the control voltage Vcont to be output from the voltage generation part 4014 in a manner that depends on the ambient temperature Ta by referring to the control table 40112.

For example, as illustrated in FIG. 9, the control table 40112 stores therein information that causes the control voltage Vcont to be output in such a way that the bias current I1 that is greater than the bias current I0 is supplied to the output transistor 102 in the time period T2 in a square pulse-like waveform when the ambient temperature Ta is equal to or less than a predetermined threshold value (for example, 0 degrees C.). Further, the control voltage Vcont is output in such a way that the bias current I1 returns to the bias current I0 at the start of the time period T3.

Further, in FIG. 9, the control table 40112 stores therein information that causes the control voltage Vcont to be output in such a way that the bias current I1 that is greater than the bias current I0 is supplied to the output transistor 102 in a square pulse-like waveform in the time period T5 that is immediately before the timing at which the average output power P6 increases to the average output power P7 when the ambient temperature Ta is equal to or less than the predetermined threshold value (for example, 0 degrees C.). Further, the control voltage Vcont is output in such a way that the bias current I1 returns to the bias current I0 at the start of the time period T6. As described above, with the power amplifying circuit of the fourth embodiment, in addition to the case where the average output power is increased from zero, even in the case where the average output power is increased from a certain value, the bias current may be increased.

Further, as illustrated in FIG. 10, the magnitude of the bias current in the time period T2 and the magnitude of the bias current in the time period T5 may be controlled in a manner that depends on the magnitude of the average output power P5 and the magnitude of the average output power P7, respectively. In this case, the bias control part 401 outputs the control voltage Vcont in such a way that the magnitude of the bias current supplied to the output transistor 102 varies in a manner that depends on the average output power of the transmitting signal. Comparing FIG. 9 and FIG. 10, for example, the bias current in the time period T2 is the bias current I1 in FIG. 9, and the bias current in the time period T2 is a bias current I7 that has a smaller current value than the bias current I1 in FIG. 10. Further, instead of being controlled in a manner that depends on the magnitude of the average output power P5 and the magnitude of the average output power P7, the control may alternatively be performed in a manner that depends on the differences in the average output power before and after the timing at which the average power increases, that is, the difference P5 in the average output power at the timing at which the time period T2 ends and the difference (P7-P6) in the average output power at the timing at which the time period T5 ends. In this case, the bias control part 401 outputs the control voltage Vcont in such a way that the magnitude of the bias current supplied to the output transistor 102 varies in a manner that depends on an increased amount at the timing at which the average output power of the transmitting signal increases.

Further, as illustrated in FIG. 11, the control table 40112 stores therein information that causes the control voltage Vcont to be output in such a way that the bias current I0 is supplied to the output transistor 102 even in the time period T2 when the ambient temperature Ta is higher than the predetermined threshold value (for example, 0 degrees C.).

According to the power amplifying circuit 10 of the fourth embodiment, even in the case where the FDD system is used, the breakdown voltage of the output transistor 102 can be increased to, for example, a value comparable to that of the case where the ambient temperature is higher than the threshold value.

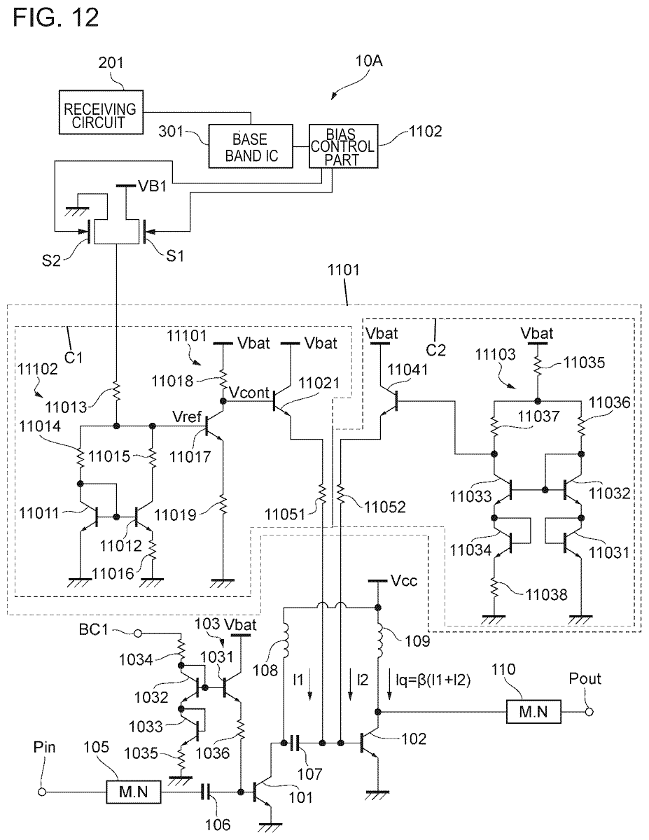

The fifth embodiment is described. FIG. 12 is a circuit diagram of a power amplifying circuit 10A of the fifth embodiment. The power amplifying circuit 10A includes a transistor 101, an output transistor 102, a bias circuit 103, matching circuits 105 and 110, capacitors 106 and 107, inductors 108 and 109, and resistive elements 1036, 11051, and 11052. Further, the power amplifying circuit 10A includes a bias circuit part 1101 including a bias circuit C1 and a bias circuit C2. Further, the power amplifying circuit 10A includes a receiving circuit 201, a base band IC 301, a bias control part 1102, and switches S1 and S2. The power amplifying circuit 10A performs amplification for communication using a TDD system.

The bias circuit C1 (first bias circuit) includes a reference voltage generation circuit 11102 and a control transistor part 11101. The reference voltage generation circuit 11102 includes transistors 11011 and 11012 and resistive elements 11013, 11014, 11015, and 11016. The reference voltage generation circuit 11102 is a current mirror circuit and has a characteristic of having a small dependence of reference voltage Vref on temperature. A power source voltage VB1 is supplied to the reference voltage generation circuit 11102 via the resistive element 11013.

The control transistor part 11101 includes transistors 11017 and 11021 and resistive elements 11018 and 11019. A power source voltage Vbat is supplied to the collector of the transistor 11017 via the resistive element 11018. The emitter of the transistor 11017 is connected to ground via the resistive element 11019. The reference voltage Vref is supplied to the base of the transistor 11017 from the reference voltage generation circuit 11102. The collector of the transistor 11017 is connected in such a way that a control voltage Vcont is supplied to the base of the transistor 11021.

The power source voltage Vbat is supplied to the collector of the transistor 11021. The emitter of the transistor 11021 is connected to the base of the output transistor 102 via the resistive element 11051. The transistor 11021 supplies a bias current I1 (first bias current) to the base of the output transistor 102 on the basis of the control voltage Vcont supplied to the base of the transistor 11021.

The bias circuit C2 (second bias circuit) includes a reference voltage generation circuit 11103 and a transistor 11041. The reference voltage generation circuit 11103 includes transistors 11031, 11032, 11033, and 11034 and resistive elements 11035, 11036, 11037, and 11038. The reference voltage generation circuit 11103 supplies a base voltage to the transistor 11041. The reference voltage generation circuit 11103 is a current mirror circuit and is a bias circuit that has the characteristic of having a small dependence of output current on temperature.

The transistor 11041 outputs a bias current I2 to the output transistor 102 on the basis of a voltage from the reference voltage generation circuit 11103. Note that the bias currents I1 and 12 of the fifth embodiment are different from the bias currents I1 and 12 of the first to fourth embodiments.

An idle current Iq that flows into the collector of the output transistor 102 connected to the bias circuits C1 and C2 is calculated as Iq=β(I1+I2) where R is the current gain of the output transistor 102.

Operation of the power amplifying circuit 10A in the case where the temperature decreased is described. The reference voltage Vref to be output from the reference voltage generation circuit 11102 has almost no dependence on the ambient temperature. On the other hand, an ON voltage of the transistor 11017, which is a base-emitter voltage of the transistor 11017, increases with a decrease of the ambient temperature. Accordingly, a current ic flowing through the transistor 11017 and the resistive element 11018 decreases with a decrease of the ambient temperature.

The decrease in the current ic reduces a voltage drop at the resistive element 11018, and thus the control voltage Vcont applied to the transistor 11021 increases. When the control voltage Vcont increases, the bias current I1 increases.

On the other hand, the bias current I2 (second bias current) to be supplied from the bias circuit C2 has almost no dependence on the ambient temperature.

The bias control part 1102 outputs signals that switch between ON and OFF of the switches S1 and S2 on the basis of the switching signal from the base band IC 301.

The switch S1 switches between the connection to the bias circuit C1 and the connection to the power line that supplies the power source voltage VB1. The switch S2 switches between the connection to the bias circuit C1 and the connection to the ground. That is to say, the switch S1 and the switch S2 enable the switching between ON and OFF of the bias circuit C1. The power amplifying circuit 10A can cause both the bias circuit C1 and the bias circuit C2 to operate or cause only the bias circuit C2 to operate by controlling ON and OFF of the switches S1 and S2. Specifically, when the switch S1 is ON, both the bias circuits C1 and C2 operate, and when the switch S2 is ON, only the bias circuit C2 operates. The switch S1 and the switch S2 can be referred to as a bias selection circuit.

For example, the switches S1 and S2 are each made up of a field effect transistor. Note that the switches S1 and S2 and the bias control part 1102 may be integrated on the same semiconductor chip as that of the power amplifying circuit 10A or may be integrated on a semiconductor chip different from that of the power amplifying circuit 10A.

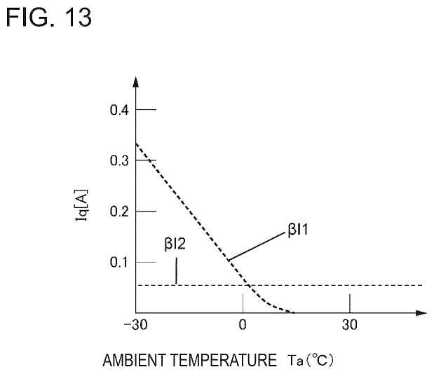

FIG. 13 illustrates the relationship between the ambient temperature Ta and an idle current βI1 from the bias circuit C1 and the relationship between the ambient temperature Ta and an idle current βI2 from the bias circuit C2 in the power amplifying circuit 10A. βI1 becomes zero at about 10 degrees C. because the bias current I1 decreases with an increase of the ambient temperature Ta due to the foregoing operation. (I2 does not vary with the ambient temperature Ta and stays constant.

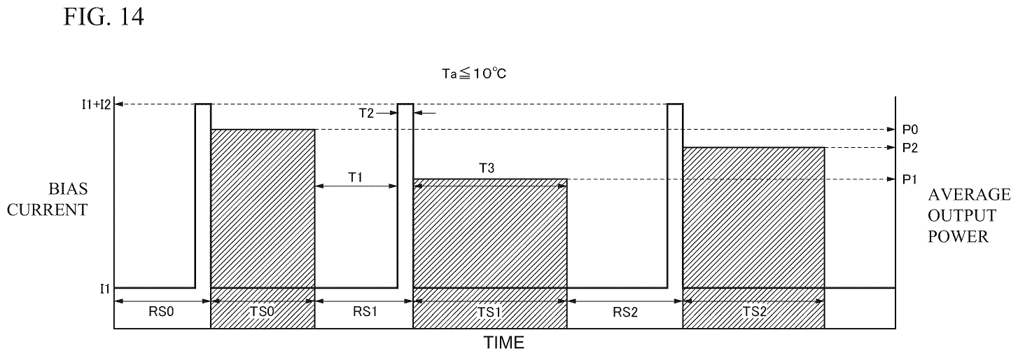

Referring to FIG. 14, the control of the bias current (or the bias voltage) performed by the bias control part 1102 is described.

FIG. 14 is a graph illustrating the variation of the bias current with time and the variation of the average output power of the output transistor 102 with time in communication of a TDD system.

The control of the bias control part 1102 is described. Here, the description is provided while focusing on the receiving time slot RS1 and the transmitting time slot TS1.

The bias control part 1102 (a) obtains a signal (switching signal) that distinguishes between the transmitting time slot and the receiving time slot from the base band IC 301, and (b) outputs a signal that switches between ON and OFF of the switches S1 and S2 in response to the switching signal. Specifically, the bias control part 1102 turns on the switch S1 in the time period T2. The bias control part 1102 turns on the switch S2 in the time periods T1 and T3.

That is to say, the bias control part 1102 performs the control in such a way that in the time period T2 that is immediately before the time period T3 where the amplification operation starts, in addition to the bias current I2 from the bias circuit C2, a bias current is supplied to the output transistor 102 from the bias circuit C1 that outputs the bias current I1 when the ambient temperature is low.

For example, as illustrated in FIG. 14, when the ambient temperature Ta is equal to or less than a predetermined threshold value (for example, 10 degrees C.), in the time period T2, a bias current I1+I2 that is obtained by adding the bias current I1 to the bias current I2 is supplied to the output transistor 102 in a square pulse-like waveform. Further, the bias circuits C1 and C2 are selected in such a way that the bias current I1+I2 returns to the bias current I1 at the start of the time period T3.

Further, when the ambient temperature Ta is higher than the predetermined threshold value (for example, 10 degrees C.), in the time period T2, the bias current I1+I2 that is obtained by adding the bias current I1 to the bias current I2 is supplied to the output transistor 102 in a square pulse-like waveform. However, when the ambient temperature Ta is higher than the predetermined threshold value (for example, 10 degrees C.), the bias current I1 becomes an extremely small value. Accordingly, also in the time period T2, the bias current supplied to the output transistor 102 is substantially equal in magnitude to the bias current I2 in the time periods T1 and T3.

As described above, in the power amplifying circuit 10A, when the ambient temperature Ta is equal to or less than the predetermined threshold value, the bias current supplied to the output transistor 102 is increased in the time period T2 that is close to the time immediately before the start of the amplification of the transmitting signal. Because of this, the temperature of the output transistor 102 can be increased to an ordinary temperature. Because of this, the breakdown voltage of the transistor 102 at the start of transmitting can be increased to, for example, a value comparable to that of the case where the ambient temperature is higher than the threshold value. The power amplifying circuit 10A is realized using analog circuits without necessarily involving digital processing on the basis of the temperature sensor, and thus, the digital signal process can be made simpler and easier to use.

Further, as described in the second embodiment and the third embodiment, in the power amplifying circuit 10A, the magnitude of the bias current may be increased transiently in a manner that depends on the average output power or the ambient temperature or both. Further, as is the case with the fourth embodiment, the power amplifying circuit 10A may also perform the amplification for a FDD system.

Note that each of the embodiments described above is provided to facilitate understanding of the present disclosure and is not to be construed as limiting the present disclosure. The present disclosure can be modified or improved without necessarily departing from its spirit, and the present disclosure also includes equivalents thereof. That is to say, ones obtained by suitably modifying designs of the respective embodiments by those skilled in the art are also included within the scope of the present disclosure as long as they include features of the present disclosure. For example, each element included in each embodiment as well as its arrangement, material, condition, shape, size, and the like are not limited to those exemplified, and may be suitably changed. Needless to say, each embodiment is for illustrative purposes only, and constituent elements illustrated in different embodiments may be combined or partially exchanged. Resulting embodiments are also included in the scope of the present disclosure so long as the characteristic features of the present disclosure are included.

<1>

A power amplifying circuit comprising:
an output transistor that amplifies a radio frequency signal and outputs an amplified signal;
a bias circuit part that supplies a bias current or voltage to the output transistor; and
a bias control part that is connected to the bias circuit part and includes a control circuit that increases the bias current or voltage when an ambient temperature is equal to or less than a predetermined threshold value, wherein
in consecutive time periods of a first time period, a second time period, and a third time period, when output of the output transistor in the third time period is greater than output of the output transistor in the first time period, the bias control part increases the bias current or voltage in the second time period in such a manner as to become higher than the bias current or voltage of a case where the ambient temperature is higher than the predetermined threshold value.
   <2>

The power amplifying circuit according to <1>, wherein
the bias control part further includes a temperature sensor that measures the ambient temperature.
   <3>

The power amplifying circuit according to <1> or <2>, wherein
the radio frequency signal is a transmitting signal in a transmitting time slot of a time division duplex system, and
the third time period is included in a transmitting time slot of the time division duplex system, and the first time period and the second time period are included in a receiving time slot.
   <4>

The power amplifying circuit according to any one of <1> to <3>, wherein
the radio frequency signal is a transmitting signal of a frequency division duplex system.
   <5>

The power amplifying circuit according to any one of <1> to <4>, further comprising:
a receiving circuit that obtains a switching signal that indicates timing of switching from the second time period to the third time period, wherein
the control circuit increases the bias current or voltage on a basis of the ambient temperature and the switching signal.
   <6>

The power amplifying circuit according to <5>, wherein
the receiving circuit further obtains an output display signal that indicates a first average output of output of the output transistor in the third time period and a second average output of output of the output transistor in the first time period, and
the control circuit increases the bias current or voltage on a basis of the ambient temperature, the switching signal, and the output display signal.
   <7>

The power amplifying circuit according to any one of <1> to <6>, wherein the control circuit increases the bias current or voltage in a square pulse-like manner in the second time period.

<8>

The power amplifying circuit according to any one of <1> to <7>, wherein
at a time of start of the third time period, the control circuit decreases the bias current or voltage that has been increased in the second time period.
   <9>

The power amplifying circuit according to any one of <1> to <8>, further comprising:
a receiving circuit that obtains an output display signal that indicates a first average output of output of the output transistor in the third time period and a second average output of output of the output transistor in the first time period, wherein
the control circuit increases the bias current or voltage in the second time period in a manner that depends on a difference between the first average output and the second average output on a basis of the output display signal.
   <10>

The power amplifying circuit according to any one of <1> to <9>, wherein
the control circuit increases the bias current or voltage in the second time period in a manner that depends on the ambient temperature.
   <11>

The power amplifying circuit according to <1>, further comprising:
a reference voltage generating circuit that generates a reference voltage; and
a control transistor part that includes a control transistor, the reference voltage being supplied to a base of the control transistor, the control transistor outputting a control voltage that increases with a decrease of the ambient temperature on a basis of the ambient temperature and the reference voltage.
   <12>

The power amplifying circuit according to <11>, further comprising:
a bias selection circuit, wherein
the bias circuit part includes a first bias circuit and a second bias circuit, and
the bias selection circuit switches a supply state on a basis of a control signal from the bias control part in such a way that both the first bias circuit and the second bias circuit or only the second bias circuit supplies the bias current or voltage to the output transistor.
   <13>

The power amplifying circuit according to <12>, wherein
the bias selection circuit switches the supply state in such a way that
in the second time period, the first bias circuit supplies the bias current or voltage to the output transistor, and
in the first time period and the third time period, the second bias circuit supplies the bias current or voltage to the output transistor.

### REFERENCE SIGNS LIST

10, 10A Power amplifying circuit
102 Output transistor
104 Bias circuit
1101 Bias circuit part
401, 1102 Bias control part
4011 Control circuit

1. A power amplifying circuit comprising:
an output transistor configured to amplify a radio frequency signal and to output an amplified signal;
a bias circuit configured to supply a bias current or voltage to the output transistor; and
a bias controller that is connected to the bias circuit and that comprises a control circuit configured to increase the bias current or voltage when an ambient temperature is equal to or less than a predetermined threshold value, wherein in first, second, and third consecutive time periods, when output of the output transistor in the third time period is greater than output of the output transistor in the first time period and the second time period, the bias controller is configured to increase the bias current or voltage in the second time period such that the bias current or voltage becomes higher than the bias current or voltage in a case where the ambient temperature is higher than the predetermined threshold value.

2. The power amplifying circuit according to claim 1, wherein the bias controller further comprises a temperature sensor configured to measure the ambient temperature.

3. The power amplifying circuit according to claim 1,
wherein the radio frequency signal is a transmitting signal in a transmitting time slot of a time division duplex system, and
wherein the third time period is in a transmitting time slot of the time division duplex system, and the first time period and the second time period are in a receiving time slot.

4. The power amplifying circuit according to claim 1, wherein the radio frequency signal is a transmitting signal of a frequency division duplex system.

5. The power amplifying circuit according to claim 1, further comprising:
a receiving circuit configured to obtain a switching signal that indicates timing of switching from the second time period to the third time period,
wherein the control circuit is configured to increase the bias current or voltage on a basis of the ambient temperature and the switching signal.

6. The power amplifying circuit according to claim 5,
wherein the receiving circuit further obtains an output display signal that indicates a first average output of output of the output transistor in the third time period and a second average output of output of the output transistor in the first time period and the second time period, and
wherein the control circuit is configured to increase the bias current or voltage on a basis of the ambient temperature, the switching signal, and the output display signal.

7. The power amplifying circuit according to claim 1, wherein the control circuit is configured to increase the bias current or voltage in a square pulse-like manner in the second time period.

8. The power amplifying circuit according to claim 1, wherein at a start of the third time period, the control circuit is configured to decrease the bias current or voltage that has been increased in the second time period.

9. The power amplifying circuit according to claim 1, further comprising:
a receiving circuit configured to obtain an output a display signal that indicates a first average output of output of the output transistor in the third time period and a second average output of output of the output transistor in the first time period and the second time period,
wherein the control circuit is configured to increase the bias current or voltage in the second time period in a manner that depends on a difference between the first average output and the second average output on a basis of the output display signal.

10. The power amplifying circuit according to claim 1, wherein the control circuit is configured to increase the bias current or voltage in the second time period in a manner that depends on the ambient temperature.

11. The power amplifying circuit according to claim 1, further comprising:
a reference voltage generating circuit configured to generate a reference voltage; and
a control transistor that includes a control transistor, the reference voltage being supplied to a base of the control transistor, the control transistor being configured to output a control voltage that increases with a decrease of the ambient temperature on a basis of the ambient temperature and the reference voltage.

12. The power amplifying circuit according to claim 11, further comprising:
a bias selection circuit,
wherein the bias circuit comprises a first bias circuit and a second bias circuit, and
wherein the bias selection circuit is configured to switch a supply state on a basis of a control signal from the bias controller such that both the first bias circuit and the second bias circuit or only the second bias circuit supplies the bias current or voltage to the output transistor.

13. The power amplifying circuit according to claim 12, wherein the bias selection circuit is configured to switch the supply state such that:
in the second time period, the first bias circuit and the second bias circuit are configured to supply the bias currents or voltages to the output transistor, and
in the first time period and the third time period, the second bias circuit is configured to supply the bias current or voltage to the output transistor.
